(19) United States
(12) Patent Application Publication
(10) Pub. No.: US 2024/0258764 A1
(43) Pub. Date: Aug. 1, 2024

(54) METHOD FOR MANUFACTURING OPTOELECTRONIC COMPONENTS, AND OPTOELECTRONIC COMPONENTS

(71) Applicant: ams-OSRAM International GmbH, Regensburg (DE)

(72) Inventors: Markus Keidler, Pettendorf (DE); Martin Mueller, Bernhardswala (DE)

(21) Appl. No.: 18/561,240

(22) PCT Filed: May 23, 2022
(86) PCT No.: PCT/EP2022/063946

§ 371 Date: Nov. 15, 2023

(30) Foreign Application Priority Data
May 27, 2021 (DE) 10 2021 113 701.2

(51) Int. Cl. H01S 5/02; B23K 26/53; B23K 101/40; H01S 5/02315; H01S 5/0237

(52) U.S. Cl. CPC H01S 5/0201; B23K 26/53; H01S 5/02315; H01S 5/0237; B23K 2101/40

(57) ABSTRACT

In an embodiment a method includes providing at least one semiconductor wafer, which has a semiconductor layer sequence and a plurality of single diode elements arranged next to and connected to one another, generating thermally induced predetermined breaking locations in the semiconductor layer sequence between the single diode elements using first laser radiation, arranging the semiconductor wafer on a carrier, and connecting the semiconductor wafer to the carrier, the single diode elements being at least partially separated from one another at the thermally induced predetermined breaking locations, wherein thermally induced predetermined breaking locations are generated in the carrier using second laser radiation so that the carrier has a plurality of carrier elements connected to one another, and wherein the carrier elements are separated from one another at the predetermined breaking locations by a connecting process.

### CROSS-REFERENCE TO RELATED APPLICATIONS

This patent application is a national phase filing under section 371 of PCT/EP2022/063946, filed May 23, 2022, which claims the priority of German patent application 10 2021 113 701.2, filed May 27, 2021, each of which is incorporated herein by reference in its entirety.

### TECHNICAL FIELD

Optoelectronic components, which may have one or more emitter elements, are specified. Methods for the production thereof are furthermore specified. For example, the components are edge-emitting semiconductor components which emit laser radiation. The components may furthermore be vertical emitters, the emitter elements being for example arranged in a 2D array.

### BACKGROUND

In laser bar components, the problem is for example known that when the laser bars are mounted on carriers, for example heat sinks, an internal stress of the laser bars leads to semilunate bending (so-called SMILE) and therefore to deviations of the light-emitting regions of the laser bar components from a straight line. If the laser bars are bent back into a straight line in order to avoid the semilunate bending and to achieve a uniform thermal contact face/contact, this leads to large stresses in edge regions and therefore to a polarization change of the emitted laser light. Although there is the possibility of mounting the laser bars respectively as individual laser diode chips on carriers, this requires relatively large carriers in order to provide electrical contact regions, for example, so that a fill factor becomes correspondingly smaller and the adjustment, or the production outlay for the laser bar components, increases.

### SUMMARY

Embodiments provide optoelectronic components having improved optical properties. Further embodiments provide more efficient methods for producing optoelectronic components.

According to at least one embodiment of a method for producing optoelectronic components, said method comprises:
providing at least one semiconductor wafer, which has a semiconductor layer sequence and a plurality of single diode elements arranged next to one another and connected to one another, for example mechanically connected to one another, which respectively comprise a part of the semiconductor layer sequence,
generating thermally induced predetermined breaking locations in the semiconductor layer sequence between the single diode elements using laser radiation,
arranging the semiconductor wafer on a carrier,
connecting the semiconductor wafer to the carrier, the single diode elements being at least partially separated from one another at the thermally induced predetermined breaking locations.

For example, the list indicated above consists of method steps carried out successively.

The single diode elements are miniature emitter units, which are created by structuring from the semiconductor wafer and are suitable for emitting electromagnetic radiation, for example infrared or visible radiation. For example, the semiconductor wafer may be a laser bar and the single diode elements may be laser diode elements which are suitable for emitting electromagnetic radiation with a coherent fraction. The coherent fraction of electromagnetic radiation is laser radiation. The coherent fraction may, for example, be laser radiation in the fundamental mode of a resonator of the component, this resonator being formed by side faces or laser facets.

The at least partial separation of the single diode elements advantageously leads to a reduction of internal stresses of the semiconductor wafer and furthermore to the single diode elements being arranged on the carrier in an at least approximately straight line without semilunate bending. In the finished components, this may inter alia produce an improvement in the optical properties, for example the polarization properties. Furthermore, owing to the reduced stresses, the edge regions are also available as the light-emitting regions so that the component may be reduced in its lateral extent or the usable area may correspondingly be increased.

The method for structuring the semiconductor wafer using laser radiation may be referred to as stealth dicing. The laser radiation leads to thermally induced mechanical stress in desired separating regions, or on desired separating lines, which by further mechanical loading leads to a directional fracture profile along the separating regions, or separating lines. The wavelength of the laser radiation used is for example between 1000 and 1100 nm, in particular 1064 nm. The wavelength is in particular contingent on which radiation is absorbed sufficiently strongly in the material.

In general, stealth dicing leads to no changes in the surface structure of the semiconductor layer sequence so that, for instance, indentations would be formed in the surface of the semiconductor layer sequence.

According to at least one embodiment, the predetermined breaking locations are arranged lying internally. In this case, the predetermined breaking locations do not reach in the vertical direction, that is to say perpendicularly to a main extent plane of the semiconductor layer sequence, or of the semiconductor wafer, as far as surfaces of the semiconductor layer sequence.

According to at least one embodiment, the semiconductor layer sequence has at least one first semiconductor layer, for example an n-conductive semiconductor layer, an active zone and at least one second semiconductor layer, for example a p-conductive semiconductor layer, the active zone being arranged between the at least one first semiconductor layer and the at least one second semiconductor layer.

The at least one first semiconductor layer, the active zone and the at least one second semiconductor layer are in particular layers grown epitaxially on a growth substrate, in which case the growth substrate may remain intact or be thinned in the finished component. The aforementioned carrier may be an element different to the growth substrate.

The active zone contains for example a sequence of individual layers, via which a quantum well structure, in particular a single quantum well (SQW) structure or multiple quantum well (MQW) structure is formed.

For the semiconductor layers of the semiconductor layer sequence, materials based on arsenide, phosphide or nitride compound semiconductors may for example be envisioned. “Based on arsenide, phosphide or nitride compound semiconductors” means in the present context that the semiconductor layers contain AlₙGaₘIn₁₋ₙ₋ₘAs, AlₙGaₘIn₁₋ₙ₋ₘP, InₙGa₁₋ₙAsₘP₁₋ₘ or AlₙGaₘIn₁₋ₙ₋ₘN, where 0≤ n≤1, 0≤ m≤1 and n+m≤1. This material need not necessarily have a mathematically exact composition according to the formula above. Rather, it may have one or more dopants and additional constituents which essentially do not alter the characteristic physical properties of the AlₙGaₘIn₁₋ₙ₋ₘAs, AlₙGaₘIn₁₋ₙ₋ₘP, InₙGa₁₋ₙAsₘP₁₋ₘ or AlₙGaₘIn₁₋ₙ₋ₘN material. For the sake of simplicity, however, the formula above contains only the essential constituents of the crystal lattice (Al, Ga, In, As or P or N) even though these may be partially replaced with small amounts of further substances. A quinternary semiconductor consisting of Al, Ga, In (group III) and P and As (group V) is also conceivable.

According to at least one embodiment, the carrier comprises a base body, which in particular has a comparatively high thermal conductivity. For example, the base body contains or consists of a metal, a ceramic material and/or semiconductor material. For example, the following materials may be considered for the base body: Si, SiC, AlN, CuW, Ge. The carrier may have surface metallizations, for example consisting of Cu, which are applied onto the base body. The surface metallizations are used, for example, as terminal regions or contact regions of the component.

According to at least one embodiment of the method, the single diode elements are separated from one another by the connecting process. For example, the connecting process may be a soldering process. Because of the thermomechanical stresses which occur during the soldering, the semiconductor wafer breaks apart at the predetermined breaking locations so that the semiconductor layer sequence is divided at least for the most part, preferably fully, in the vertical direction at the predetermined breaking locations and the single diode elements are no longer connected to one another and are separated from one another, for instance fully separated.

According to at least one embodiment of the method, the single diode elements may be separated from one another by a thermomechanical process. The thermomechanical process may be carried out in addition to the connecting process, for example by additional heating or cooling of the semiconductor wafer and/or carrier, the semiconductor wafer breaking apart at the predetermined breaking locations because of the heating or cooling. The thermomechanical process may, for example, be carried out simultaneously with the connecting process. It is, however, also possible for the thermomechanical process to take place with a time offset from the connecting process.

According to at least one embodiment of the method, thermally induced predetermined breaking locations are generated in the carrier using laser radiation, that is to say using stealth dicing as already described above, so that the carrier has a plurality of carrier elements connected to one another. The carrier elements may respectively be assigned in a one-to-one correspondence to a single diode element. The number of carrier elements may in this case correspond to the number of single diode elements. Furthermore, the predetermined breaking locations may be arranged lying internally so that they do not reach in the vertical direction, that is to say transversely with respect to a main extent plane of the carrier, as far as surfaces of the carrier.

The introduction of predetermined breaking locations into the carrier may be carried out before or after the process of connecting to the semiconductor wafer.

According to at least one embodiment of the method, the carrier elements are separated from one another at the predetermined breaking locations by the connecting process and/or by a thermomechanical process. As already mentioned above, the connecting process may be a soldering process. Furthermore, the thermomechanical process may be additional heating or cooling of the semiconductor wafer and/or carrier, which contributes to the carrier breaking apart and is carried out in addition to the connecting process.

According to at least one embodiment, the semiconductor wafer is connected to the carrier by a connecting agent. If the semiconductor wafer is connected to the carrier by a soldering process, the connecting agent is a solder, which is formed from a metallic material and for example contains at least one of the following materials: Sn, Zn, Ag, Au, Cu, In, Pb.

The connecting agent may already be applied onto the carrier and structured in a suitable way before the connecting process.

Advantageously, in the case of structuring of the semiconductor wafer, connecting agent and carrier, singulation into optoelectronic components may already take place by the connecting process and/or thermomechanical process. The method thus allows self-singulation so that no additional singulation steps, for example by fracture, are necessary. The method is therefore distinguished by particular efficiency.

According to at least one embodiment of the method, a sacrificial structure in the semiconductor layer sequence, which is removed after the semiconductor wafer is connected to the carrier, is generated between the plurality of single diode elements. The sacrificial structure may comprise regions of the semiconductor layer sequence that are respectively arranged between two neighbouring single diode elements.

In one advantageous configuration of the method, electrical contact regions of the carrier are exposed by the removal of the sacrificial structure. The electrical contact regions are in this case already applied onto the base body of the carrier before the connecting process. Each single diode element may in this case be assigned at least one electrical contact region. For example, the electrical contact regions are respectively intended for contacting one of the semiconductor layers of the semiconductor layer sequence of the single diode elements.

According to at least one embodiment of the method, the connecting process is carried out for a plurality of semiconductor wafers and carriers simultaneously. In this case, a plurality of semiconductor wafers and carriers, on which a semiconductor wafer is respectively arranged, are arranged above one another. For example, the connecting process may be carried out in conjunction with a thermal pretreatment, for instance before or after mirroring of laser facets of the semiconductor wafers configured as laser bars. The mirroring of the laser facets of the laser bars may take place simultaneously. It is possible for a number of up to 500 semiconductor wafers, or laser bars, and carriers to be stacked above one another and processed together. So-called spacer bars may in this case respectively be arranged between two semiconductor wafer-carrier units arranged above one another.

The optoelectronic components described below, comprising components which respectively have a single diode element or a plurality of single diode elements, may be produced using the method described above. Features described in connection with the method may therefore also be used for the optoelectronic components, and vice versa.

According to at least one embodiment of an optoelectronic component, the latter comprises a carrier, a semiconductor layer sequence, which is arranged on the carrier and comprises an active zone suitable for generating electromagnetic radiation, and a plurality of single diode elements arranged next to one another, which are respectively formed at least partially from the semiconductor layer sequence, the single diode elements being at least partially separated from one another.

The single diode elements are spatially separated from one another by an intermediate space, for example by an air gap, which extends at least partially through the semiconductor layer sequence in the vertical direction. The intermediate space can reduce electrical or optical crosstalk between the single diode elements.

Furthermore, the single diode elements are preferably electrically drivable individually. This may, for example, be achieved by the single diode elements respectively being unambiguously assigned a first electrical contact structure of a first polarity and a second electrical contact structure of a second polarity, preferably in a one-to-one correspondence. A current may in this case be locally imprinted into the single diode elements. In the event of a failure of particular single diode elements, energy losses may therefore be reduced significantly in comparison with a component that has continuous single diode elements.

According to at least one embodiment of an optoelectronic component, the latter comprises a carrier element and a single diode element, which is arranged on the carrier element. The optoelectronic component has, in particular, one single diode element. The single diode element comprises a semiconductor layer stack, which has an active zone suitable for generating electromagnetic radiation, and at least one side face having traces of thermal pre-damage by laser radiation. The traces result from the use of stealth dicing during the production of the component. The traces constitute a conspicuous pattern typical of stealth dicing, which may for example be seen with a light microscope. The semiconductor layer stack is preferably a part of the semiconductor layer sequence of the semiconductor wafer which is separated with the aid of stealth dicing. Furthermore, the carrier element is preferably a part of the carrier which is separated with the aid of stealth dicing. Correspondingly, at least one side face of the carrier element may have traces of thermal pre-damage by laser radiation.

According to at least one embodiment, the optoelectronic component, which in particular has one single diode element, comprises a first electrical contact structure which is intended for electrically contacting the first semiconductor layer. Furthermore, the component may have a second electrical contact structure which is intended for electrically contacting the second semiconductor layer.

The carrier element may have a base body element, which is preferably a part of the base body of the carrier which is separated with the aid of stealth dicing.

The optoelectronic components may be edge-emitting layers having a power of from 1 mW to 100 W per single diode element, which emit laser radiation on a laser facet arranged transversely with respect to the front and rear sides of the at least one single diode element.

The optoelectronic components are suitable in particular for applications in materials processing, for LIDAR (Light Detection and Ranging, or Light Imaging, Detection and Ranging) systems, and for use for hard drives, CD-ROMs and Blu-ray or optical data transmission.

### BRIEF DESCRIPTION OF THE DRAWINGS

Further advantages, advantageous embodiments and developments will be apparent from the following exemplary embodiments which are described in conjunction with the figures, in which:

FIGS. 1A and 1B show various method steps of a method according to a first exemplary embodiment for producing optoelectronic components;

FIG. 2 shows a cross-sectional view of an optoelectronic component according to a first exemplary embodiment;

FIGS. 3A and 3B show various method steps of a method according to a comparative example for producing laser bar components;

FIGS. 4A and 4B show various method steps of a method according to a second exemplary embodiment for producing optoelectronic components;

FIGS. 5A and 5B show cross-sectional views of optoelectronic components according to further exemplary embodiments;

FIG. 6 shows a method step of a method according to a third exemplary embodiment for producing optoelectronic components;

FIG. 7 shows a method step of a method according to a fourth exemplary embodiment for producing optoelectronic components; and

FIG. 8A shows a plan view of a semiconductor wafer and FIG. 8B shows a perspective view of an optoelectronic component according to a further exemplary embodiment.

### DETAILED DESCRIPTION OF ILLUSTRATIVE EMBODIMENTS

In the exemplary embodiments and figures, elements which are the same or of the same type, or which have the same effect, may respectively be provided with the same reference signs. The elements represented and their size proportions with respect to one another are not necessarily to be regarded as true to scale; rather, individual elements may be represented in exaggeratedly large size for better representability and/or better understanding.

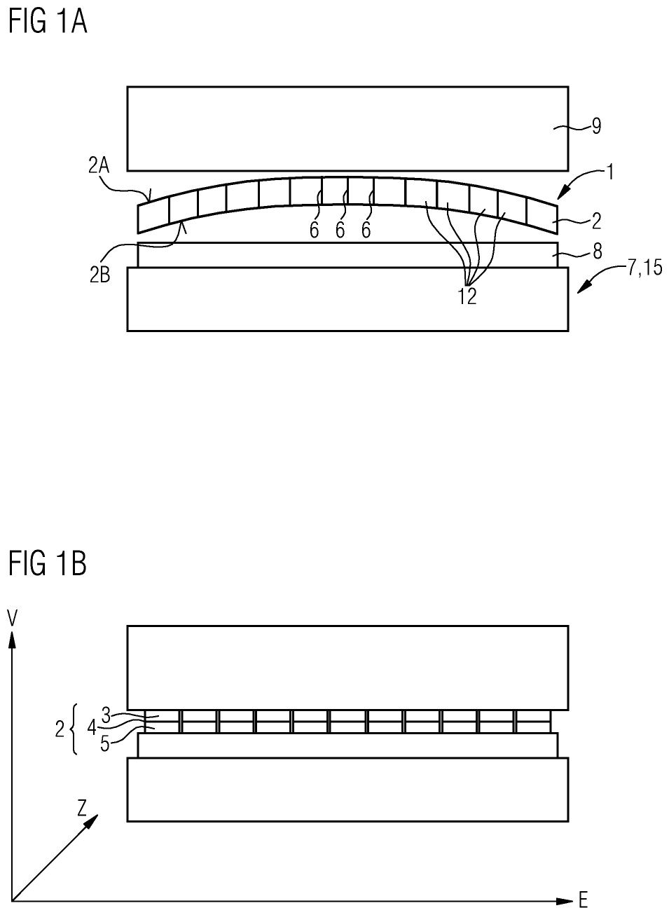

In a first exemplary embodiment of a method for producing optoelectronic components, a semiconductor wafer 1, which is represented in a cross-sectional view in FIG. 1A, is provided.

A carrier 7, which is represented in a cross-sectional view in FIG. 1A, is furthermore provided. The semiconductor wafer 1 may be arranged on the carrier 7 using a mounting tool 9.

The semiconductor wafer 1 comprises a semiconductor layer sequence 2 and a plurality of single diode elements 12 arranged next to one another and connected to one another, for example mechanically, which respectively comprise a part of the semiconductor layer sequence 2 (cf. FIG. 1A). The single diode elements 12 are miniature emitter units, which are created by structuring from the semiconductor wafer 1.

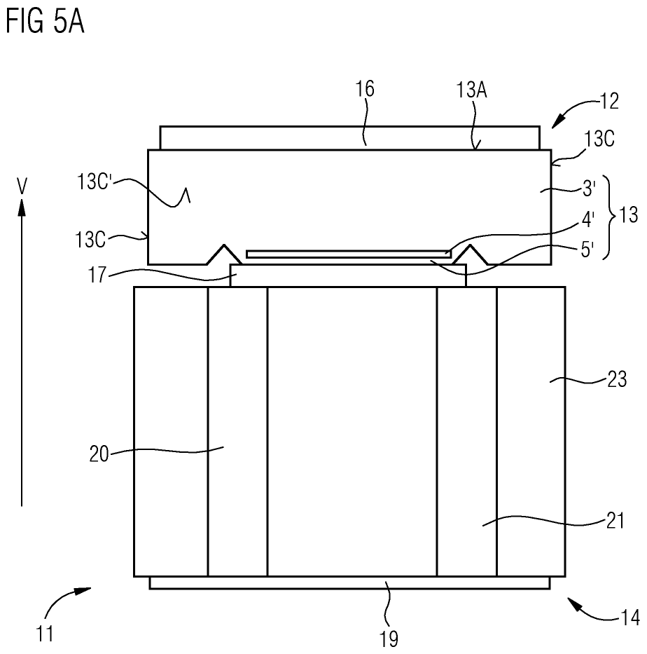

The single diode elements 12 may have a strip-shaped configuration and be intended for emitting electromagnetic radiation in the finished component. For example, the semiconductor wafer 1 is a laser bar and the single diode elements 12 are laser diode elements, which are intended for emitting electromagnetic radiation with a coherent fraction. The semiconductor wafer 1 may have a plurality of strip-shaped contact regions 16 (cf. FIG. 5A) on a front side facing away from the carrier 7, which respectively define a single diode element 12 and are used for electrical contacting in the finished component.

The semiconductor layer sequence 2 has at least one first semiconductor layer 3, for example an n-conductive semiconductor layer, an active zone 4 suitable for generating radiation, and at least one second semiconductor layer 5, for example a p-conductive semiconductor layer, the second semiconductor layer 5 being arranged on a side facing toward the carrier 7 and the first semiconductor layer 3 being arranged on a side of the semiconductor layer sequence 2 facing away from the carrier (cf. FIG. 1B). It is, however, also possible for the first semiconductor layer 3 to be a p-conductive layer and correspondingly for the second layer 5 to be an n-conductive layer.

As already mentioned above, materials based on arsenide, phosphide or nitride compound semiconductors may be envisioned for the semiconductor layer sequence 2.

Furthermore, a base body 15 of the carrier 7 may have a comparatively high thermal conductivity. For example, the base body 15 contains or consists of a metal, a ceramic material and/or a semiconductor material. For example, the following materials may be considered for the base body 15: Si, SiC, AlN, CuW, Ge.

In the semiconductor layer sequence 2, thermally induced predetermined breaking locations 6 are generated between the single diode elements 12 using laser radiation, the wavelength of which is for example between 1000 and 1100 nm, for instance 1064 nm. This process is also referred to as stealth dicing. The predetermined breaking locations 6 are in this case located in the interior of the semiconductor layer sequence 2 and do not reach as far as a first and second main face 2A, 2B of the semiconductor layer sequence 2, which bound the semiconductor layer sequence 2 on a front side and a rear side.

For example, the predetermined breaking locations 6 are generated along separating lines which, in a plan view of the semiconductor wafer 1, result in a line grid that is arranged in a main extent plane E-Z of the semiconductor layer sequence 2, or of the semiconductor wafer 1.

The generation of the predetermined breaking locations 6 takes place, for example, before the semiconductor wafer 1 is arranged on the carrier 7.

In the first exemplary embodiment, the semiconductor wafer 1 is connected to the carrier 7 after it has been arranged thereon. This is done by a soldering process, using, as a connecting agent 8 between the semiconductor wafer 1 and the carrier 7, a solder which is formed from a metallic material, and which for example contains at least one of the following materials: Sn, Zn, Ag, Au, Cu, In, Pb.

By the connecting or soldering process and the temperatures that prevail therein, the mechanical stress induced in the semiconductor wafer 1 is further increased in the planes of the predetermined breaking locations 6 parallel to a V-Z plane, which is arranged perpendicularly to the main extent plane E-Z. The single diode elements 12 are already separated from one another at the thermally induced predetermined breaking locations 6 by the connecting process or by an additional thermomechanical process (cf. FIG. 1B). The thermomechanical process may involve heating or cooling of the semiconductor wafer 1 and/or carrier 7, which contributes to the semiconductor wafer 1 breaking apart.

The at least partial separation of the single diode elements 12 leads to a reduction of internal stresses of the semiconductor wafer 1 and furthermore causes the emitting regions of the single diode elements 12 to be arranged in an at least approximately straight line without semilunate bending.

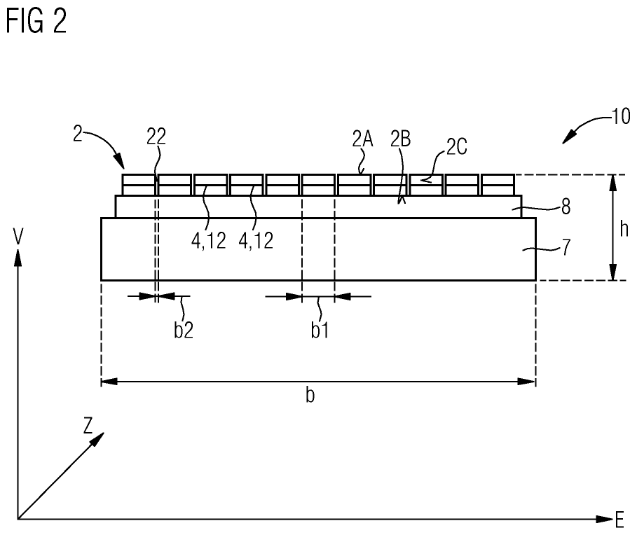

FIG. 2 represents an optoelectronic component 10 which may be produced using the method according to the first exemplary embodiment. For example, the optoelectronic component 10 is a laser bar component which is intended for emitting laser radiation.

The optoelectronic component 10 comprises a carrier 7 and a semiconductor layer sequence 2, which is arranged on the carrier 7. The semiconductor layer sequence 2 is connected to the carrier 7 by a connecting agent 8, for instance a solder. The semiconductor layer sequence 2 comprises an active zone 4 suitable for generating electromagnetic radiation. For example, the active zone 4 is suitable for generating infrared or visible laser radiation. The laser radiation may be emitted on a side face 2C or laser facet of the component 1, which is arranged transversely with respect to the first main face 2A and the second main face 2B of the semiconductor layer sequence 2.

The optoelectronic component 10 may have a lateral extent b of about 10 mm and a height h of about 200 μm-1200 μm. The lateral extent b is in this case determined parallel to the main extent plane E-Z of the semiconductor layer sequence 2, which is spanned by the two lateral directions E, Z. The height h is determined parallel to a vertical direction V, which runs perpendicularly to the main extent plane E-Z.

The optoelectronic component 10 comprises a plurality of single diode elements 12 or laser diode elements arranged next to one another, which are respectively formed at least partially from the semiconductor layer sequence 2, the single diode elements 12 being separated from one another, for example mechanically.

For example, the semiconductor wafer 1 comprises 20 single diode elements 12. The single diode elements 12 may have a lateral extent b1 of between 100 μm and 2500 μm.

By the at least partial separation of the single diode elements 12, stresses are reduced so that the component 10 has improved optical properties, for example improved polarization properties. Furthermore, owing to the reduced stresses, edge regions are also available as light-emitting regions. Using such a component 10, high powers may be generated in light guides inter alia.

The single diode elements 12 are respectively separated spatially from one another by an intermediate space 22, for example by an air gap. The latter can reduce electrical or optical crosstalk between the single diode elements 12. The intermediate spaces 22 may in this case have a lateral extent b2 of between 0.05 μm and 50 μm, in particular between 0.05 μm and 5 μm. The lateral extent b2 may for instance depend on a difference between the thermal expansion coefficients of the semiconductor layer sequence 2 and of the carrier 7.

Furthermore, the single diode elements 12 are preferably electrically drivable individually. A current may in this case respectively be imprinted locally into the single diode elements 12. In the event of a failure of particular single diode elements 12, energy losses may therefore be reduced significantly in comparison with a component that has continuous laser diode elements.

In order to produce a plurality of optoelectronic components having only one single diode element 12, the component 10 may be structured further by the carrier 7 being divided along the intermediate spaces 22.

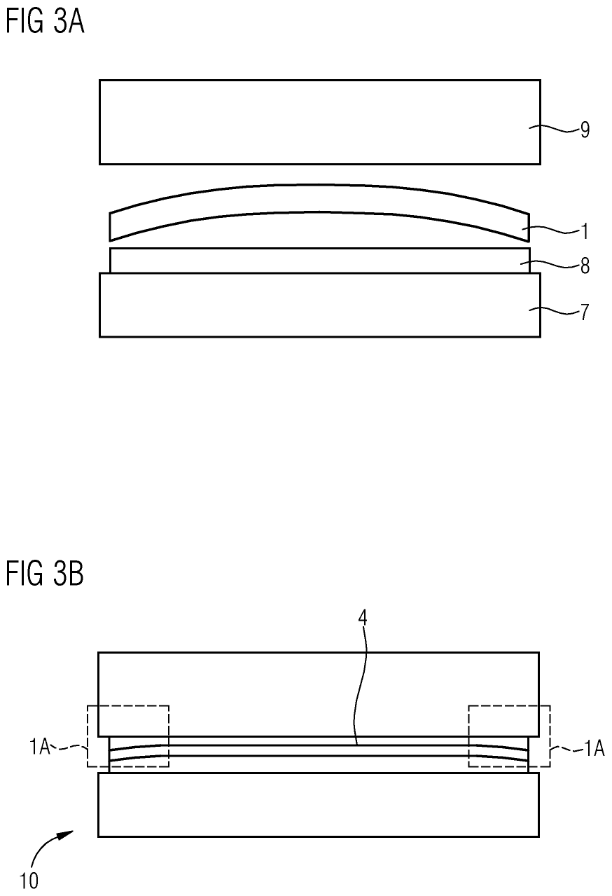

In the comparative example of a method as represented in FIGS. 3A and 3B, a semiconductor wafer 1, which is a monolithic laser bar 1 which exhibits semilunate bending because of internal stresses, is mounted on a carrier 7. In the laser bar component 10 generated in this way, the problem arises that deviations from a straight line occur in the active zone 4. Furthermore, polarization changes for the emitted radiation occur in the edge regions 1A. These problems can be prevented in the optoelectronic components according to the exemplary embodiments.

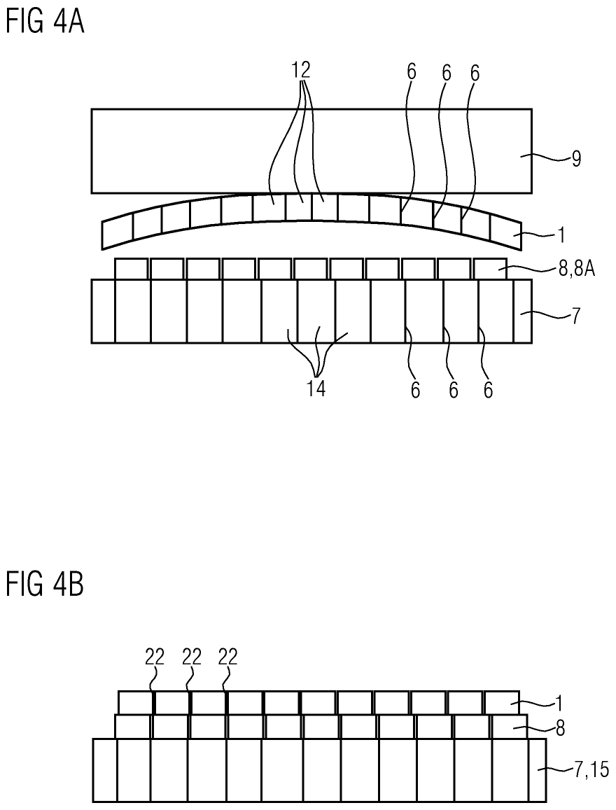

In the second exemplary embodiment of a method as represented in FIGS. 4A and 4B, thermally induced predetermined breaking locations 6 are generated using laser radiation, that is to say by stealth dicing as already described above, not only in the semiconductor wafer 1, which is for example a laser bar, but also in the carrier 7, so that the carrier 7 has a plurality of carrier elements 14 connected to one another. The predetermined breaking locations 6 may also be arranged lying internally in the carrier 7 so that they do not reach as far as surfaces of the carrier 7.

The carrier elements 14 may respectively be assigned in a one-to-one correspondence respectively to a single diode element 12, so that the number of carrier elements 14 corresponds to the number of laser diode elements 12.

The single diode elements 12 and the carrier elements 14 are respectively separated from one another at the predetermined breaking locations 6 by the connecting process and/or by a thermomechanical process

For mechanically connecting the single diode elements 12 to the carrier elements 14, a connecting agent 8, which may already be applied onto the carrier 7 and structured into connecting agent regions 8A before the connecting process, is arranged between the elements 12, 14, in which case each carrier element 14 may be assigned a connecting agent region 8A in a one-to-one correspondence.

FIG. 5A shows an exemplary embodiment of an optoelectronic component 11 which may be produced using a method according to the second exemplary embodiment and is intended for emitting laser radiation.

The component 11 comprises a carrier element 14 and precisely one single diode element 12, which is arranged on the carrier element 14. The single diode element 12 has a semiconductor layer stack 13, which comprises a first semiconductor layer 3′, a second semiconductor layer 5′ and an active zone 4′ suitable for generating electromagnetic radiation, which is arranged between the first and second semiconductor layers 3′, 5′. The first semiconductor layer 3′ may be an n-doped layer. Furthermore, the second semiconductor layer 5′ may be a p-doped layer.

The semiconductor layer stack 13 is a part of the semiconductor layer sequence 2 of a semiconductor wafer 1 which is separated in particular with the aid of stealth dicing, and to this extent has the properties of the semiconductor layer sequence 2 which have already been mentioned above. Furthermore, the carrier element 14 is preferably a part of the carrier 7 which is separated for example with the aid of stealth dicing, and to this extent has the properties of the carrier 7 which have already been mentioned above.

The carrier element 14 has a base body element 23, which is for example a part of the base body 15 of the carrier 7 which is separated with the aid of stealth dicing.

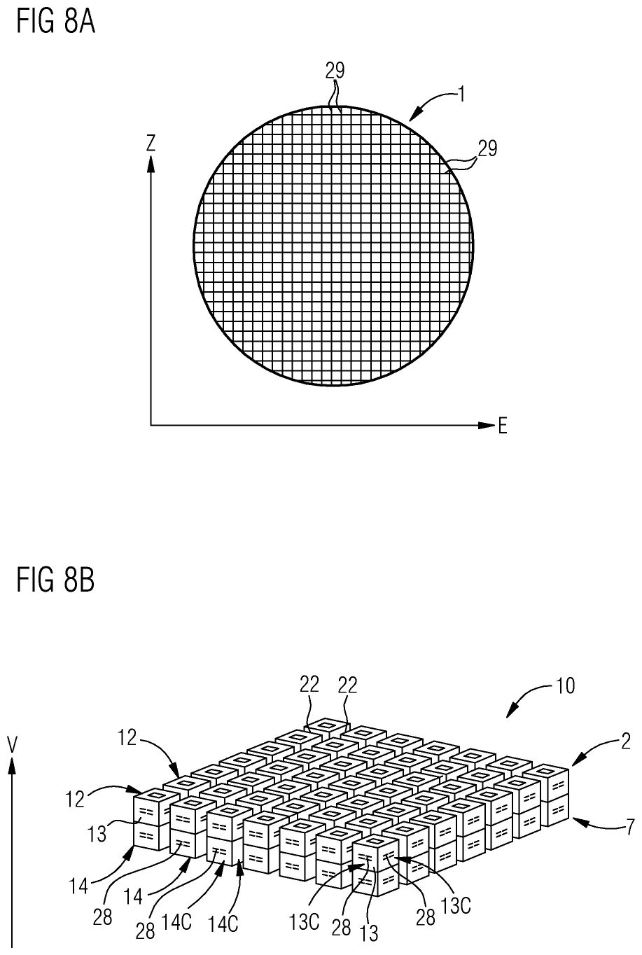

The semiconductor layer stack 13 has a mirrored laser facet and a laser facet 13C′, arranged opposite the latter, for emitting laser radiation. The mirrored laser facet and the laser facet 13C′ are arranged transversely with respect to side faces 13C of the semiconductor layer stack 13, which have been generated during the separation of the single diode elements 12 with the aid of stealth dicing. These side faces 13C therefore have traces 28 of thermal pre-damage by laser radiation, which may for example be seen with a light microscope (cf. FIG. 8B).

On the base body element 23, a second electrical contact region 17, which is electrically conductively connected to the second semiconductor layer 5′, is arranged on a front side facing toward the single diode element 12. A first electrical contact region 16, which is electrically conductively connected to the first semiconductor layer 3′ and can be electrically contacted from the outside using a connecting agent, for example a bond wire, is further provided on a first main face 13A of the layer stack 13.

For electrical contacting the second contact region 17, the carrier element 14 has a second electrical terminal region 19, which is arranged on the base body element 23, on a rear side facing away from the single diode element 12.

Furthermore, the carrier element 14 comprises a first through-contact 20 and a second through-contact 21, which extend through the base body element 23 in the vertical direction V and electrically conductively connect the second electrical contact region 17 to the second electrical terminal region 19. Such a multiple arrangement of the through-contacts 20, 21 is technically expedient.

The first electrical contact region 26 is part of a first contact structure of the component 11, which is intended for electrically contacting the first semiconductor layer 3′. Furthermore, the second electrical contact region 17, the first and second through-contacts 20, 21 and the second electrical terminal region 19 are part of a second contact structure of the component 11, which is intended for electrically contacting the second semiconductor layer 5′.

FIG. 5B represents a further exemplary embodiment, in which the first electrical contact region 16, like the second electrical contact region 17, is arranged on a second main face 13B of the layer stack 13, which faces toward the carrier element 14. In this case, the carrier element 14 has three through-contacts 20, 21, 25. The first through-contact 20 in this case establishes an electrical connection between the second electrical contact region 17 and the second electrical terminal region 19. Further, the first electrical contact region 16 is electrically conductively connected by the further through-contacts 21, 25 to a first electrical terminal region 18. The first electrical contact region 16, the through-contacts 21, 25 and the first electrical terminal region 18 are in this case part of a first contact structure of the component 11, which is intended for electrically contacting the first semiconductor layer 3′. Furthermore, the second electrical contact region 17, the through-contact 20 and the second electrical terminal region 19 are part of a second contact structure of the component 11, which is intended for electrically contacting the second semiconductor layer 5′.

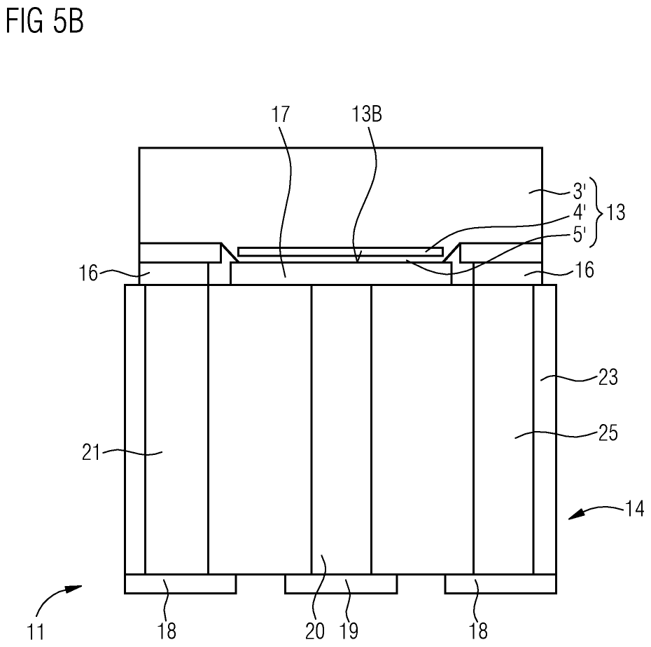

FIG. 6 represents a further exemplary embodiment of a method, in which a sacrificial structure 26, which is removed after the connection of the semiconductor wafer to the carrier 7, is generated in the semiconductor layer sequence 2 between the plurality of single diode elements 12. The sacrificial structure 26 comprises regions 26A of the semiconductor layer sequence which are respectively arranged between two neighbouring single diode elements 12. The regions 26A may have a lateral extent b3 of between 50 μm and 200 μm.

By the removal of the sacrificial structure 26, the second electrical contact regions 17 are regionally exposed. The exposed regions 24 are used for electrically contacting the second electrical contact regions 17 from the outside, for example using a bond wire.

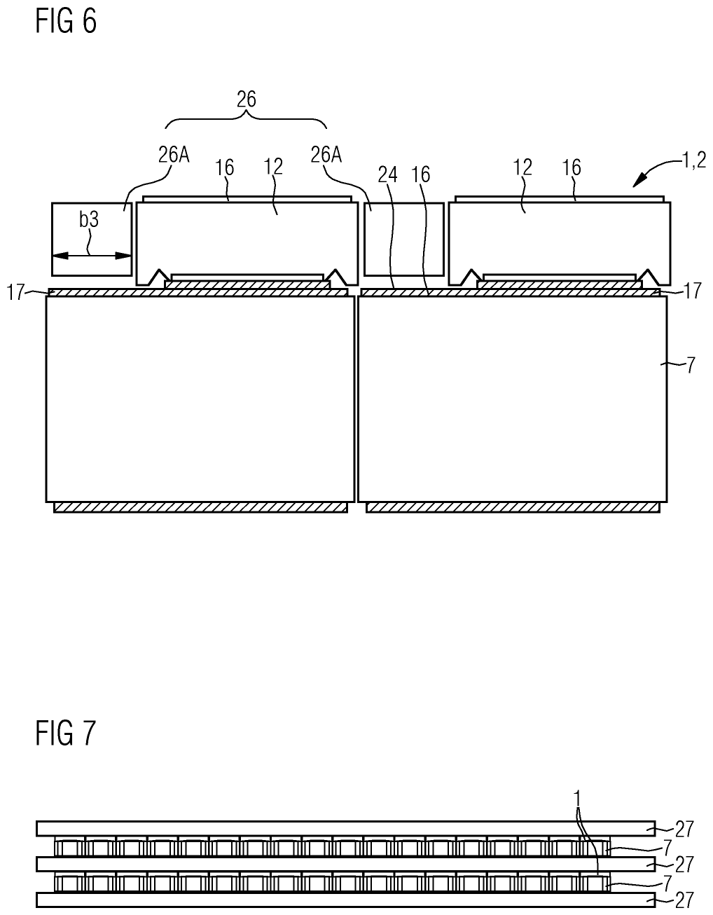

FIG. 7 represents a further exemplary embodiment of a method. In this case, the connecting process is carried out simultaneously for a plurality of semiconductor wafers 1 and carriers 7. A plurality of semiconductor wafers 1 and carriers 7, on which a semiconductor wafer 7 is respectively arranged, are in this case arranged above one another. For example, the connecting process may be carried out in conjunction with a thermal pretreatment, for instance before or after mirroring of laser facets of the semiconductor wafers 1 configured as laser bars. The mirroring of the laser facets of the laser bars 1 may take place simultaneously. It is possible for a number of up to 500 semiconductor wafers, or laser bars 1, and carriers 7 to be stacked above one another and processed together. So-called spacer bars 27 may in this case respectively be arranged between two semiconductor wafer-carrier units arranged above one another.

FIG. 8B shows a further exemplary embodiment of an optoelectronic component 10. The component 10 comprises a carrier 7 and a semiconductor layer sequence 2, which is arranged on the carrier 7, as well as a plurality of single diode elements 12 arranged in a 2D array, which are respectively formed at least partially from the semiconductor layer sequence 2, the single diode elements 12 being at least partially separated from one another by intermediate spaces 22. The emission of the generated radiation, which is for example incoherent, may take place in the vertical direction V.

The single diode elements 12 respectively have a semiconductor layer stack 13 with a plurality of side faces 13C, at least some of the side faces 13C having traces 28 of thermal pre-damage by laser radiation. The traces 28 result from the generation of predetermined breaking locations in the semiconductor layer sequence 2 of the semiconductor wafer 1 using stealth dicing and the subsequent separation at the predetermined breaking locations, which in this exemplary embodiment lead to separating lines 29 that follow the pattern a cross grid (cf. FIG. 8A).

The carrier 7 further has a plurality of carrier elements 14, which are at least partially separated from one another by intermediate spaces 22. The carrier elements 14 have a plurality of side faces 14C, at least some of the side faces 14C having traces 28 of thermal pre-damage by laser radiation, which result from the generation of predetermined breaking locations in the carrier 7 using stealth dicing and the subsequent separation at the predetermined breaking locations.

The carrier elements 14 and the single diode elements 12 have a substantially rectangular, for instance square, outline. The geometry of the carrier elements 14 or of the single diode elements 12 is for example determined by the crystal structure of the semiconductor crystals used, which is for example hexagonal in the case of GaN.

The description with the aid of the exemplary embodiments does not restrict the invention to this description. Rather, the invention comprises any new feature and any combination of features, which in particular includes any combination of features in the patent claims, even if this feature or this combination is not itself explicitly specified in the patent claims or exemplary embodiments.

1-12. (canceled)

13. A method for producing optoelectronic components, the method comprising:
providing at least one semiconductor wafer, which has a semiconductor layer sequence and a plurality of single diode elements arranged next to one another and connected to one another, and which respectively comprise a part of the semiconductor layer sequence;
generating thermally induced predetermined breaking locations in the semiconductor layer sequence between the single diode elements using first laser radiation;
arranging the semiconductor wafer on a carrier; and
connecting the semiconductor wafer to the carrier by carrying out a connecting process, the single diode elements being at least partially separated from one another at the thermally induced predetermined breaking locations,
wherein thermally induced predetermined breaking locations are generated in the carrier using second laser radiation so that the carrier has a plurality of carrier elements connected to one another, and
wherein the carrier elements are separated from one another at the predetermined breaking locations by the connecting process.

14. The method according to claim 13, wherein the single diode elements are separated from one another by the connecting process.

15. The method according to claim 13, wherein the connecting process is a soldering process.

16. The method according to claim 13, wherein the single diode elements are separated from one another by a thermomechanical process.

17. The method according to claim 13, wherein the semiconductor wafer is connected to the carrier by a connecting agent.

18. The method according to claim 13, wherein a sacrificial structure in the semiconductor layer sequence, which is removed after the semiconductor wafer is connected to the carrier, is generated between the plurality of single diode elements.

19. The method according to claim 18, wherein electrical contact regions of the carrier are exposed by the removal of the sacrificial structure.

20. The method according to claim 13, wherein a plurality of semiconductor wafers and carriers, on which a semiconductor wafer is respectively arranged, are arranged above one another and the connecting process of connecting semiconductor wafers and carriers is carried out simultaneously.

21. The method according to claim 20, wherein mirroring of laser facets of the semiconductor wafers, which are configured as laser bars, is carried out simultaneously after the connecting process.

22. The method according to claim 13, wherein generating the predetermined breaking locations in the semiconductor layer sequence is carried out such that the predetermined breaking locations are lying internally and do not reach as far as surfaces of the semiconductor layer sequence.

23. The method according to claim 13, wherein generating the predetermined breaking locations in the carrier is carried out such that the predetermined breaking locations are lying internally and do not reach as far as surfaces of the carrier.

24. The method according to claim 13, wherein the semiconductor wafer is connected to the carrier by a connecting agent, wherein the connecting agent is applied onto the carrier and structured before the connecting process, wherein the single diode elements is separated from one another by the connecting process, and wherein a separation into singulated optoelectronic components takes place by the connecting process.

25. An optoelectronic component comprising:
a carrier;
a semiconductor layer sequence, which is arranged on the carrier and comprises an active zone configured to generate electromagnetic radiation; and
a plurality of single diode elements arranged next to one another, which are respectively formed at least partially from the semiconductor layer sequence,
wherein the single diode elements are at least partially separated from one another.

26. An optoelectronic component comprising:
a carrier element; and
a single diode element, which is arranged on the carrier element and comprises a semiconductor layer stack, which has an active zone configured to generate electromagnetic radiation and at least one side face,
wherein at least one side face of the semiconductor layer stack has traces of thermal pre-damage by first laser radiation.

27. The optoelectronic component according to claim 26, wherein at least one side face of the carrier element has traces of thermal pre-damage by second laser radiation.
